(19) United States
(12) Patent Application Publication
(10) Pub. No.: US 2025/0016951 A1
(43) Pub. Date: Jan. 9, 2025

(54) ELECTRONIC APPARATUS

(71) Applicant: Lenovo (Singapore) Pte. Ltd., Singapore (SG)

(72) Inventors: Yuki Saigusa, Kanagawa (JP); Ryota Watanabe, Kanagawa (JP); Atsushi Ohyama, Kanagawa (JP); Kengo Sano, Kanagawa (JP)

(73) Assignee: Lenovo (Singapore) Pte. Ltd., Singapore (SG)

(21) Appl. No.: 18/735,550

(22) Filed: Jun. 6, 2024

(30) Foreign Application Priority Data
Jul. 6, 2023 (JP) 2023-111794

(51) Int. Cl. H05K 7/20; G06F 1/20

(52) U.S. Cl. CPC H05K 7/20154; G06F 1/203; H05K 7/2039

(57) ABSTRACT

An electronic apparatus includes: a chassis; a heat generation element provided in the chassis; a heat transfer member in contact with the heat generation element in a heat-transferable manner; and one or a plurality of heat dissipation mechanisms configured to cool the heat transfer member. The heat dissipation mechanism includes a first cooling device configured to cool a first main surface of the heat transfer member, and a second cooling device configured to cool a second main surface of the heat transfer member opposite to the first main surface. The first cooling device includes a first heat dissipation plate in contact with the first main surface in a heat-transferable manner, and a first blower mechanism configured to blow a gas to come into contact with the first heat dissipation plate.

### CROSS-REFERENCE TO RELATED APPLICATIONS

This application claims priority to Japanese Patent Application No. 2023-111794 filed on Jul. 6, 2023, the contents of which are hereby incorporated herein by reference in their entirety.

### TECHNICAL FIELD

The present invention relates to an electronic apparatus.

### BACKGROUND

In electronic apparatuses such as a notebook-type personal computer (laptop PC), a cooling device may be mounted in a chassis (see, for example, Japanese Unexamined Patent Application Publication No. 2010-55310). The cooling device is, for example, a heat dissipation fin and a fan for cooling an electronic component such as a CPU.

In the electronic apparatus, since a size of the cooling device is large, there may be a case where an installation space of other components is affected. Therefore, it is required to save a space in the chassis.

### SUMMARY

One or more embodiments of the present invention provide an electronic apparatus capable of saving a space in a chassis.

According to one or more embodiments of the present invention, there is provided an electronic apparatus including: a chassis; a heat generation element provided in the chassis; a heat transfer member in contact with the heat generation element in a heat-transferable manner; and one or a plurality of heat dissipation mechanisms configured to cool the heat transfer member, in which the heat dissipation mechanism includes a first cooling device configured to cool a first main surface of the heat transfer member, and a second cooling device configured to cool a second main surface of the heat transfer member opposite to the first main surface, the first cooling device includes a first heat dissipation plate in contact with the first main surface in a heat-transferable manner, and a first blower mechanism configured to blow a gas to come into contact with the first heat dissipation plate, and the second cooling device includes a second heat dissipation plate in contact with the second main surface in a heat-transferable manner, and a second blower mechanism configured to blow a gas to come into contact with the second heat dissipation plate.

In one or more embodiments, the first blower mechanism brings the gas into contact with the first heat dissipation plate by blowing the gas in a direction facing the first heat dissipation plate, and the second blower mechanism brings the gas into contact with the second heat dissipation plate by blowing the gas in a direction facing the second heat dissipation plate.

In one or more embodiments, the plurality of heat dissipation mechanisms includes a first heat dissipation mechanism and a second heat dissipation mechanism, the heat transfer member includes a main portion in contact with the heat generation element in a heat-transferable manner, a first expansion portion that extends from one side edge of the main portion to an outer side, and a second expansion portion that extends from the other side edge of the main portion to another outer side, the first heat dissipation mechanism is provided at the first expansion portion, and the second heat dissipation mechanism is provided at the second expansion portion.

In one or more embodiments, the heat transfer member is a heat transport member in which an operating fluid is enclosed in a sealed space formed between a pair of main plates facing each other.

According to one or more embodiments of the present invention, it is possible to provide an electronic apparatus capable of saving a space in a chassis.

### BRIEF DESCRIPTION OF THE DRAWINGS

FIG. 1 is a plan view of an electronic apparatus according to one or more embodiments.

FIG. 2 is a plan view illustrating an internal structure of a second chassis of the electronic apparatus according to one or more embodiments.

FIG. 3 is a plan view of a heat transfer member and a heat dissipation mechanism of the electronic apparatus according to one or more embodiments.

FIG. 4 is a cross-sectional diagram of the heat transfer member and the heat dissipation mechanism of the electronic apparatus according to one or more embodiments.

### DETAILED DESCRIPTION OF THE INVENTION

### [Electronic Apparatus]

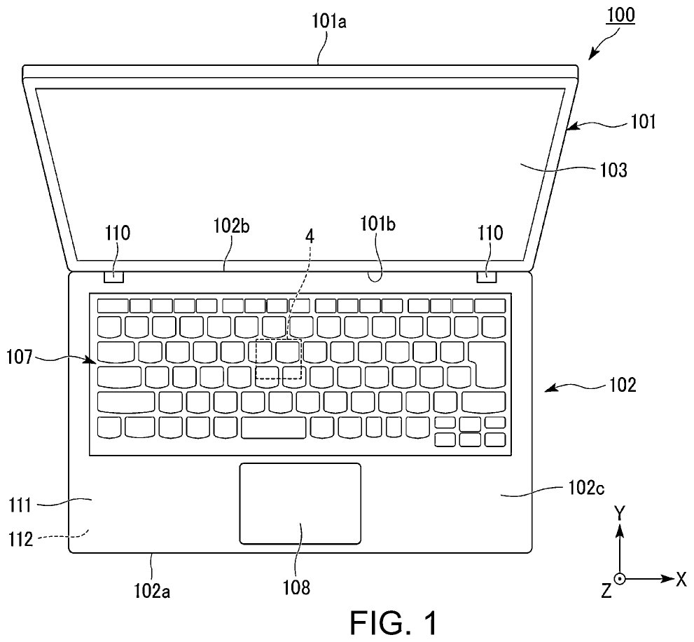

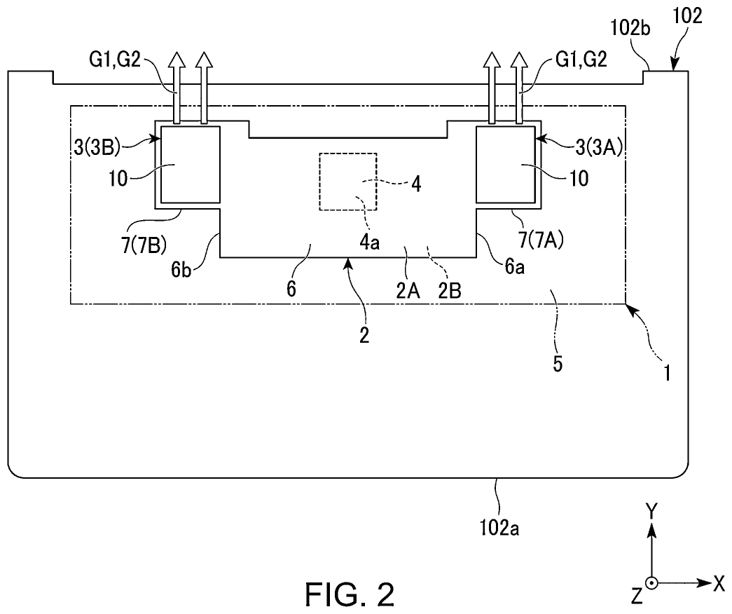

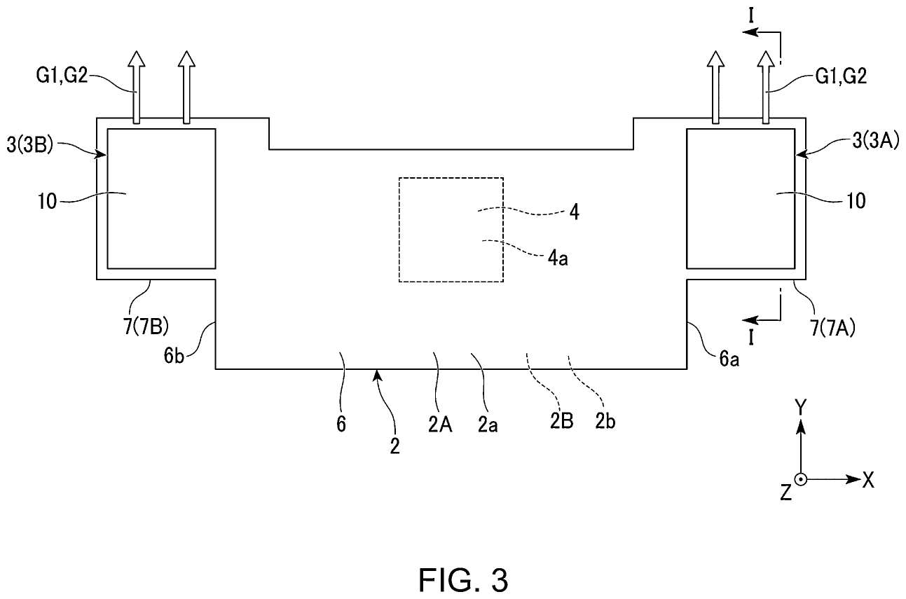

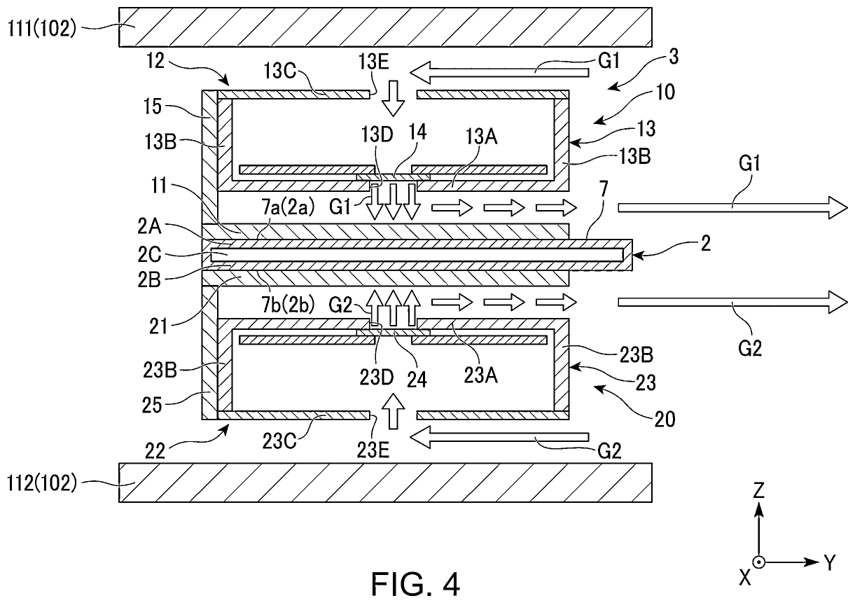

An electronic apparatus according to one or more embodiments will be described. FIG. 1 is a plan view of an electronic apparatus 100 according to one or more embodiments. FIG. 2 is a plan view illustrating an internal structure of a second chassis 102. FIG. 3 is a plan view of a heat transfer member 2 and a heat dissipation mechanism 3. FIG. 4 is a cross-sectional diagram of the heat transfer member 2 and the heat dissipation mechanism 3. FIG. 4 is a cross-sectional diagram taken along a line I-I of FIG. 3.

As illustrated in FIG. 1, the electronic apparatus 100 includes a first chassis 101, a second chassis 102, a circuit substrate 1 (see FIG. 2), a heat transfer member 2 (see FIG. 2), and a pair of heat dissipation mechanisms 3 (see FIG. 2). The electronic apparatus 100 is, for example, a laptop PC (PC: personal computer).

The first chassis 101 is also referred to as a display chassis. The first chassis 101 is provided with a display 103. The display 103 is, for example, a liquid crystal display, an organic electro-luminescence (EL) display, or the like. One end portion of the first chassis 101 is referred to as a first base end portion 101b. An end portion on a side opposite to the first base end portion 101b is referred to as a first opening end portion 101a.

The second chassis 102 (chassis) is also referred to as a system chassis. The second chassis 102 is a flat-plate-shaped case body including an upper plate 111 (first cover member) and a lower plate 112 (second cover member). The upper plate 111 and the lower plate 112 face each other. The lower plate 112 faces a mounting surface (an upper surface or the like of a desk) when the second chassis 102 is placed on the mounting surface.

A keyboard 107 and a touch pad 108 are provided on an inner surface 102c of the second chassis 102. The inner surface 102c faces the display 103 in a state in which the first chassis 101 is closed with respect to the second chassis 102.

One end portion of the second chassis 102 is referred to as a second base end portion 102b. An end portion on a side opposite to the second base end portion 102b is referred to as a second opening end portion 102a. The second base end portion 102b of the second chassis 102 is connected to the first base end portion 101b of the first chassis 101 via a hinge mechanism 110.

A positional relationship between the respective configurations may be described with reference to an XYZ orthogonal coordinate system, for the second chassis 102. A Y direction is a forward-rearward direction along the inner surface 102c. A +Y direction is a backward direction. A −Y direction is a forward direction. The −Y direction is directed from the second base end portion 102b toward the second opening end portion 102a. An X direction is orthogonal to the Y direction in a plane along the inner surface 102c. In FIG. 1, the X direction is a right-left direction. A +X direction is a right direction. A —X direction is a left direction. The X direction is orthogonal to the Y direction. A Z direction is a thickness direction of the second chassis 102. The Z direction is orthogonal to the X direction and the Y direction.

In a case where the second chassis 102 is placed on a horizontal mounting surface in a posture in which the inner surface 102c is directed upward, the Z direction is an up-down direction. A +Z direction is an upward direction. A −Z direction is a downward direction. A case where the observation is performed from the Z direction is referred to as a plan view. A plane along the X direction and the Y direction is an XY plane.

As illustrated in FIG. 2, the circuit substrate 1, the heat transfer member 2, and the heat dissipation mechanism 3 are accommodated in the second chassis 102. The circuit substrate 1 is, for example, a printed substrate (PCB). The circuit substrate 1 has a rectangular shape.

The circuit substrate 1 includes a central processing unit 4 (CPU) and a plate-shaped base material 5. The central processing unit is referred to as a “CPU”. The CPU 4 is mounted on one surface (mounting surface) of the base material 5. The CPU 4 is a processor that executes an application program to perform a general process. A first main surface 4a, which is one surface of the CPU 4, is a heat transfer region that transfers heat to the heat transfer member 2.

The CPU 4 is an electronic component which is an example of a “heat generation element”. Examples of the heat generation element include a processing device, an integrated circuit, a storage device (memory or the like), a communication module, a sensor, an optical device, a battery, a heat transport member (heat spreader, heat pipe, or the like), and the like. Examples of the processing device include a graphics processing unit (GPU), in addition to the CPU.

The heat transfer member 2 includes a material having a high thermal conductivity, for example, a metal such as copper and aluminum. The heat transfer member 2 is in contact with the CPU 4 in a heat-transferable manner. The heat transfer member 2 is in direct or indirect contact with, for example, the first main surface 4a of the CPU 4. The heat transfer member 2 may be in direct contact with the CPU 4. The heat transfer member 2 may be indirectly in contact with the CPU 4 via a thermal conductive grease, a heat dissipation sheet, or the like.

As illustrated in FIG. 3, the heat transfer member 2 has a pair of main plates 2A and 2B facing each other. The main plate 2A is an upper plate. The main plate 2B is a lower plate. The main plates 2A and 2B are parallel to the XY plane. A first main surface 2a, which is an upper surface of the main plate 2A, is an upper surface of the heat transfer member 2. The second main surface 2b, which is a lower surface of the main plate 2B, is a lower surface of the heat transfer member 2. The second main surface 2b is a surface opposite to the first main surface 2a.

A sealed space 2C is formed between the main plate 2A and the main plate 2B (see FIG. 4). The sealed space 2C is formed over an entire region of the heat transfer member 2 including a main portion 6 and expansion portions 7A and 7B. An operating fluid is enclosed in a flowable manner in the sealed space 2C in the heat transfer member 2. The heat transfer member 2 is a heat transport member. The heat transfer member 2 is, for example, a vapor chamber.

Examples of the operating fluid include water, an alternative fluorine, acetone, and butane. The operating fluid flows in a sealed space. The operating fluid is able to be phase-changed in the sealed space. For example, a wick that conveys the condensed operating fluid by a capillary phenomenon is provided in the sealed space.

The heat transfer member 2 includes the main portion 6 and a pair of expansion portions 7. The main portion 6 has a rectangular shape in the plan view. The main portion 6 may have, for example, a rectangular shape having a long side in the X direction. The main portion 6 is in direct or indirect contact with the first main surface 4a of the CPU 4.

One of the pair of expansion portions 7 is the first expansion portion 7A. The first expansion portion 7A extends from a side edge 6a (one side edge) of the main portion 6 on the +X side to the +X side (an outer side). The other of the pair of expansion portions 7 is the second expansion portion 7B. The second expansion portion 7B extends from a side edge 6b (the other side edge) of the main portion 6 on the −X side to the −X side (another outer side). The expansion portion 7 has a rectangular shape in the plan view. The “outer side” s are directions in which the side edge 6b of the main portion 6 and the side edge 6a are separated from each other. The outer side of the side edge 6a is in the −X side direction. The outer side of the side edge 6b is in the +X side direction.

As illustrated in FIG. 4, an upper surface (a surface on the +Z side) of the expansion portion 7 is the first main surface 7a. The first main surface 7a is formed to be flat. The first main surface 7a is a part of the first main surface 2a which is the upper surface of the heat transfer member 2. A lower surface (a surface on the −Z side) of the expansion portion 7 is the second main surface 7b. The second main surface 7b is formed to be flat. The second main surface 7b is a part of the second main surface 2b which is the lower surface of the heat transfer member 2. The first main surface 7a and the second main surface 7b are parallel to the XY plane.

As illustrated in FIG. 3, one of the pair of heat dissipation mechanisms 3 is a first heat dissipation mechanism 3A. The other of the pair of heat dissipation mechanisms 3 is a second heat dissipation mechanism 3B. The first heat dissipation mechanism 3A is provided in the first expansion portion 7A. The second heat dissipation mechanism 3B is provided in the second expansion portion 7B.

As illustrated in FIG. 4, the heat dissipation mechanism 3 (first heat dissipation mechanism 3A) includes a first cooling device 10 and a second cooling device 20.

The first cooling device 10 includes a first heat dissipation plate 11, a first blower mechanism 12, and a first support body 15.

The first heat dissipation plate 11 has a rectangular shape. The first heat dissipation plate 11 includes a material having a high thermal conductivity, for example, a metal such as copper and aluminum. The first heat dissipation plate 11 is stacked on the first main surface 7a of the first expansion portion 7A from above. The first heat dissipation plate 11 is in contact with the first main surface 7a of the first expansion portion 7A in a heat-transferable manner. The first heat dissipation plate 11 has, for example, an area that covers a major part region of the first main surface 7a in the plan view. The first heat dissipation plate 11 is parallel to the XY plane.

A lower surface of the first heat dissipation plate 11 is in direct or indirect contact with, for example, the first main surface 7a of the first expansion portion 7A. The first heat dissipation plate 11 may be in direct contact with the first main surface 7a. The first heat dissipation plate 11 may be indirectly in contact with the first main surface 7a via a thermal conductive grease, a heat dissipation sheet, or the like. In a case where the first heat dissipation plate 11 is in direct contact with the first main surface 7a, the first heat dissipation plate 11 is in surface contact with the first main surface 7a.

The first blower mechanism 12 is provided above the first heat dissipation plate 11. The first blower mechanism 12 is located, for example, at a position separated upward from an upper surface of the first heat dissipation plate 11.

The first blower mechanism 12 includes a case 13 and an actuator 14 (vibrating element). The case 13 includes an inner plate 13A, a side plate 13B, and an outer plate 13C. The inner plate 13A has, for example, a rectangular shape in the plan view. The inner plate 13A is parallel to, for example, the XY plane. The inner plate 13A is, for example, separated upward from the upper surface of the first heat dissipation plate 11. The inner plate 13A faces the first heat dissipation plate 11 in the up-down direction. An outlet 13D for outputting a gas G1 is formed in the inner plate 13A.

The side plate 13B stands up from a peripheral edge of the inner plate 13A. The side plate 13B has a rectangular frame shape in the plan view.

The outer plate 13C extends from an upper edge of the side plate 13B. The outer plate 13C has, for example, a rectangular shape in the plan view. The outer plate 13C is, for example, parallel to the XY plane. The outer plate 13C has the same shape as the inner plate 13A. The outer plate 13C is separated upward from the inner plate 13A. The outer plate 13C faces the inner plate 13A in the up-down direction. An inlet 13E for introducing the gas G1 into the case 13 is formed in the outer plate 13C.

The actuator 14 is in a sheet shape (film shape). The actuator 14 takes a posture intersecting the up-down direction. The actuator 14 is able to be deformed (flexure-deformed) in the thickness direction. For example, the actuator 14 vibrates in the up-down direction by being supplied with electricity. The actuator 14 operates in the thickness direction to take in the gas G1 (for example, air) from the inlet 13E into the case 13 and to output the gas G1 in the case 13 downward (in a direction facing the first heat dissipation plate 11) from the outlet 13D.

The first blower mechanism 12 is disposed to overlap with the first expansion portion 7A in the plan view. The first blower mechanism 12 has, for example, an area that covers a major part region of the first expansion portion 7A in the plan view. The first blower mechanism 12 is supported by the first support body 15. The first support body 15 extends upward from an end portion of the first heat dissipation plate 11.

The second cooling device 20 includes a second heat dissipation plate 21, a second blower mechanism 22, and a second support body 25.

The second heat dissipation plate 21 has a rectangular shape. The second heat dissipation plate 21 includes a material having a high thermal conductivity, for example, a metal such as copper and aluminum. The second heat dissipation plate 21 is stacked on the second main surface 7b of the first expansion portion 7A from below. The second heat dissipation plate 21 is in contact with the second main surface 7b of the first expansion portion 7A in a heat-transferable manner. The second heat dissipation plate 21 has, for example, an area that covers a major part region of the second main surface 7b in the plan view. The second heat dissipation plate 21 is parallel to the XY plane.

An upper surface of the second heat dissipation plate 21 is in direct or indirect contact with, for example, the second main surface 7b of the first expansion portion 7A. The second heat dissipation plate 21 may be in direct contact with the second main surface 7b. The second heat dissipation plate 21 may be indirectly in contact with the second main surface 7b via a thermal conductive grease, a heat dissipation sheet, or the like. In a case where the second heat dissipation plate 21 is in direct contact with the second main surface 7b, the second heat dissipation plate 21 is in surface contact with the second main surface 7b.

The second blower mechanism 22 is provided below the second heat dissipation plate 21. The second blower mechanism 22 is located, for example, at a position separated downward from a lower surface of the second heat dissipation plate 21.

The second blower mechanism 22 includes a case 23 and an actuator 24 (vibrating element). The case 23 includes an inner plate 23A, a side plate 23B, and an outer plate 23C. The inner plate 23A has, for example, a rectangular shape in the plan view. The inner plate 23A is parallel to, for example, the XY plane. The inner plate 23A is, for example, separated downward from the lower surface of the second heat dissipation plate 21. The inner plate 23A faces the second heat dissipation plate 21 in the up-down direction. An outlet 23D for outputting a gas G2 is formed in the inner plate 23A.

The side plate 23B hangs down from a peripheral edge of the inner plate 23A. The side plate 23B has a rectangular frame shape in the plan view.

The outer plate 23C extends from a lower edge of the side plate 23B. The outer plate 23C has, for example, a rectangular shape in the plan view. The outer plate 23C is, for example, parallel to the XY plane. The outer plate 23C has the same shape as the inner plate 23A. The outer plate 23C is separated downward from the inner plate 23A. The outer plate 23C faces the inner plate 23A in the up-down direction. An inlet 23E for introducing the gas G2 into the case 23 is formed in the outer plate 23C.

The actuator 24 is in a sheet shape. The actuator 24 takes a posture intersecting the up-down direction. The actuator 24 is able to be deformed (flexure-deformed) in the thickness direction. For example, the actuator 24 vibrates in the up-down direction by being supplied with electricity. The actuator 24 operates in the thickness direction to take in the gas G2 (for example, air) from the inlet 23E into the case 23 and to output the gas G2 in the case 23 upward (in a direction facing the second heat dissipation plate 21) from the outlet 23D.

The second blower mechanism 22 is disposed to overlap with the first expansion portion 7A in the plan view. The second blower mechanism 22 has, for example, an area that covers a major part region of the first expansion portion 7A in the plan view. The second blower mechanism 22 is supported by the second support body 25. The second support body 25 extends downward from an end portion of the second heat dissipation plate 21.

As illustrated in FIG. 3, the second heat dissipation mechanism 3B has the same structure as the first heat dissipation mechanism 3A. That is, the second heat dissipation mechanism 3B includes the first cooling device 10 and the second cooling device 20 (see FIG. 4).

The first heat dissipation plate 11 of the first cooling device 10 is stacked on the first main surface 7a of the second expansion portion 7B from above. The first heat dissipation plate 11 is in contact with the first main surface 7a of the second expansion portion 7B in a heat-transferable manner. The first blower mechanism 12 is provided above the first heat dissipation plate 11, and separated from the first heat dissipation plate 11 (see FIG. 4).

The second heat dissipation plate 21 of the second cooling device 20 is stacked on the second main surface 7b of the second expansion portion 7B from below. The second heat dissipation plate 21 is in contact with the second main surface 7b of the second expansion portion 7B in a heat-transferable manner. The second blower mechanism 22 is provided below the second heat dissipation plate 21, and separated from the second heat dissipation plate 21 (see FIG. 4).

Next, an operation of the electronic apparatus 100 will be described.

The CPU 4 may generate heat. Since the heat transfer member 2 is in direct or indirect contact with the first main surface 4a of the CPU 4, the heat of the CPU 4 is transferred to the heat transfer member 2 (specifically, the main portion 6). The heat transfer member 2 diffuses the heat generated by the CPU 4. The heat is transferred not only to the main portion 6 but also to the expansion portion 7.

Since the heat transfer member 2 is a heat transport member in which an operating fluid is enclosed in the sealed space 2C (see FIG. 4), the heat transfer from the main portion 6 to the expansion portion 7 efficiently proceeds by the flow of the operating fluid. Since the first heat dissipation plate 11 and the second heat dissipation plate 21 of the heat dissipation mechanism 3 are in contact with the expansion portion 7, the heat of the expansion portion 7 is transferred to the first heat dissipation plate 11 and the second heat dissipation plate 21.

In the first cooling device 10 of the heat dissipation mechanism 3, the first blower mechanism 12 outputs the gas G1 (for example, air) in the case 13 downward (in a direction facing the first heat dissipation plate 11) from the outlet 13D, by operating the actuator 14 in the thickness direction. The direction in which the gas G1 is output is a direction intersecting the first heat dissipation plate 11 (for example, a direction orthogonal to the first heat dissipation plate 11). The gas G1 output from the outlet 13D is blown onto an upper surface of the first heat dissipation plate 11. The gas G1 flows in the +Y direction along an upper surface of the first heat dissipation plate 11 while coming into contact with the upper surface, and is output to an outside of the second chassis 102 (see FIG. 2). The first heat dissipation plate 11 is cooled by the contact with the gas G1.

In the second cooling device 20, the second blower mechanism 22 outputs the gas G2 (for example, air) in the case 23 upward (in a direction facing the second heat dissipation plate 21) from the outlet 23D, by operating the actuator 24 in the thickness direction. The direction in which the gas G2 is output is a direction intersecting the second heat dissipation plate 21 (for example, a direction orthogonal to the second heat dissipation plate 21). The gas G2 output from the outlet 23D is blown onto a lower surface of the second heat dissipation plate 21. The gas G2 flows in the +Y direction along a lower surface of the second heat dissipation plate 21 while coming into contact with the lower surface, and is output to the outside of the second chassis 102 (see FIG. 2). The second heat dissipation plate 21 is cooled by the contact with the gas G2.

The first heat dissipation plate 11 and the second heat dissipation plate 21 are cooled, so that the expansion portion 7 is cooled. The main portion 6 is cooled by the cooling of the expansion portion 7. The CPU 4 is also cooled by the cooling of the main portion 6 (see FIG. 3).

### [Effects of Electronic Apparatus]

In the electronic apparatus 100 according to one or more embodiments, the heat dissipation mechanism 3 includes the first cooling device 10 that cools the first main surface 7a of the heat transfer member 2 and the second cooling device 20 that cools the second main surface 7b of the heat transfer member 2. The first cooling device 10 and the second cooling device 20 are able to efficiently cool both surfaces of the heat transfer member 2 (specifically, the expansion portion 7). Therefore, an installation area of the heat dissipation mechanism 3 is able to be reduced, as compared with a case where only one surface of the heat transfer member 2 is cooled.

In the electronic apparatus 100, the cooling devices 10 and 20 include the blower mechanisms 12 and 22. The blower mechanisms 12 and 22 are able to efficiently cool the heat transfer member 2, by blowing the gas G1 and G2 to come into contact with the heat dissipation plates 11 and 21 to cool the heat transfer member 2. Therefore, the installation area of the heat dissipation mechanism 3 is able to be reduced. Therefore, it is possible to save a space in the second chassis 102.

In the electronic apparatus 100, the first blower mechanism 12 and the second blower mechanism 22 are able to promote the heat transfer from the heat dissipation plates 11 and 21 to the gases G1 and G2, by blowing the gases G1 and G2 in a direction facing the heat dissipation plates 11 and 21. Therefore, the heat transfer member 2 is able to be efficiently cooled.

The electronic apparatus 100 includes the first heat dissipation mechanism 3A and the second heat dissipation mechanism 3B. The first heat dissipation mechanism 3A is provided at the first expansion portion 7A of the heat transfer member 2. The second heat dissipation mechanism 3B is provided at the second expansion portion 7B of the heat transfer member 2. In the electronic apparatus 100, since both the first heat dissipation mechanism 3A and the second heat dissipation mechanism 3B are able to cool both the expansion portions 7A and 7B of the heat transfer member 2, the heat transfer member 2 is able to be efficiently cooled.

The heat transfer member 2 is a heat transport member in which an operating fluid is enclosed in the sealed space 2C formed between the main plates 2A and 2B. Therefore, the efficiency of the heat transfer between the expansion portions 7A and 7B and the main portion 6 is able to be enhanced by the flow of the operating fluid in the sealed space 2C. Therefore, the CPU 4 is able to be efficiently cooled.

The specific configuration of the present invention is not limited to the embodiments described above, and includes a design and the like within a range that does not depart from the spirit of the present invention. Each configuration described in the embodiments described above may be combined optionally.

As illustrated in FIG. 4, in the electronic apparatus 100 according to one or more embodiments, the blower mechanisms 12 and 22 output the gases G1 and G2 in the direction facing the heat dissipation plates 11 and 21, and the direction in which the gases G1 and G2 are output is not particularly limited. For example, the blower mechanisms 12 and 22 may output the gas G1 and the gas G2 in parallel to the heat dissipation plates 11 and 21. The blower mechanisms 12 and 22 may output the gas G1 and the gas G2 in a direction (a direction intersecting the heat dissipation plates 11 and 21) inclined with respect to the heat dissipation plates 11 and 21.

As illustrated in FIG. 3, the electronic apparatus 100 according to one or more embodiments includes the two heat dissipation mechanisms 3, and the number of the heat dissipation mechanisms is not particularly limited. The number of the heat dissipation mechanisms may be one or a plurality (any number of two or more). That is, the number of the heat dissipation mechanisms may be one or a plurality.

As illustrated in FIG. 4, as the heat transfer member 2, a heat transport member in which an operating fluid is enclosed in a sealed space 2C in one or more embodiments, and the heat transfer member may be a solid plate.

The electronic apparatus is not limited to the laptop PC, and may be a tablet type terminal, a smartphone, a desktop PC, or the like.

### DESCRIPTION OF SYMBOLS

2 heat transfer member
2a first main surface
2b second main surface
2A main plate
2B main plate
2C sealed space
3 heat dissipation mechanism
3A first heat dissipation mechanism (heat dissipation mechanism)
3B second heat dissipation mechanism (heat dissipation mechanism)
4 CPU (heat generation element)
6 main portion
6a side edge (one side edge)
6b side edge (other side edge)
7A first expansion portion
7B second expansion portion
10 first cooling device
11 first heat dissipation plate
12 first blower mechanism
20 second cooling device
21 second heat dissipation plate
22 second blower mechanism
100 electronic apparatus
102 second chassis (chassis)
G1, G2 gas

What is claimed is:

1. An electronic apparatus comprising:
a chassis;
a heat generation element provided in the chassis;
a heat transfer member in contact with the heat generation element in a heat-transferable manner; and
one or a plurality of heat dissipation mechanisms configured to cool the heat transfer member,
wherein the heat dissipation mechanism includes
a first cooling device configured to cool a first main surface of the heat transfer member, and
a second cooling device configured to cool a second main surface of the heat transfer member opposite to the first main surface,
the first cooling device includes
a first heat dissipation plate in contact with the first main surface in a heat-transferable manner, and
a first blower mechanism configured to blow a gas to come into contact with the first heat dissipation plate, and
the second cooling device includes
a second heat dissipation plate in contact with the second main surface in a heat-transferable manner, and
a second blower mechanism configured to blow a gas to come into contact with the second heat dissipation plate.

2. The electronic apparatus according to claim 1,
wherein the first blower mechanism brings the gas into contact with the first heat dissipation plate by blowing the gas in a direction facing the first heat dissipation plate, and
the second blower mechanism brings the gas into contact with the second heat dissipation plate by blowing the gas in a direction facing the second heat dissipation plate.

3. The electronic apparatus according to claim 1,
wherein the plurality of heat dissipation mechanisms includes a first heat dissipation mechanism and a second heat dissipation mechanism,
the heat transfer member includes
a main portion in contact with the heat generation element in a heat-transferable manner,
a first expansion portion that extends from one side edge of the main portion to an outer side, and
a second expansion portion that extends from the other side edge of the main portion to another outer side,
the first heat dissipation mechanism is provided at the first expansion portion, and
the second heat dissipation mechanism is provided at the second expansion portion.

4. The electronic apparatus according to claim 1,
wherein the heat transfer member is a heat transport member in which an operating fluid is enclosed in a sealed space formed between a pair of main plates facing each other.
